(19) United States
(12) Patent Application Publication
(10) Pub. No.: US 2019/0157484 A1
(43) Pub. Date: May 23, 2019

(54) SOLAR CUBE DEVICE

(71) Applicant: PHILLIP SATTERFIELD, TAYLORS, SC (US)

(72) Inventor: PHILLIP SATTERFIELD, TAYLORS, SC (US)

(21) Appl. No.: 16/195,201

(22) Filed: Nov. 19, 2018

Related U.S. Application Data
(60) Provisional application No. 62/588,989, filed on Nov. 21, 2017.

(51) Int. Cl. H01L 31/05; H01L 31/054; H02S 40/38; H02S 30/10

(52) U.S. Cl. CPC H01L 31/0504; H02S 30/10; H02S 40/38; H01L 31/0543

(57) ABSTRACT

A solar cube increases efficiency by about 4.75 times in one unit of space than the standard flat solar panel. The solar cube is made of five solar panels in an open-face cube configuration that are connected in series to a battery, and a concave lens refracts light to allow all five solar panels to generate power.

This application claims the benefit of U.S. Provisional Application No. 62/588,989, filed Nov. 21, 2017, which is hereby incorporated in its entirety.

### FIELD OF THE INVENTION

The present invention relates to a solar cube configuration. More particularly, the invention pertains to a solar cube that increases efficiency by about 4.75 times in one unit of space than the standard flat solar panel.

### BACKGROUND OF THE INVENTION

The following description is not an admission that any of the information provided herein is prior art or relevant to the present invention, or that any publication specifically or implicitly referenced is prior art. Any publications cited in this description are incorporated by reference herein. Where a definition or use of a term in an incorporated reference is inconsistent or contrary to the definition of that term provided herein, the definition of that term provided herein applies and the definition of that term in the reference does not apply.

Currently, solar panels absorb a certain amount of radiant energy over a square unit of space, but current issues with needing more space to achieve preferred efficiency levels has been a significant issue hindering many homes from converting to solar energy. The aesthetic issue with homes needing to cover their entire roofs to enable solar power has also proven to be a hindrance to some potential users of solar technology. In addition, growing environmental concerns over the use of coal or nuclear energy have made the need for more efficient methods of green energy apparent.

### SUMMARY OF THE INVENTION

A solar cube device is designed to generate more electricity in one square unit of space than the standard flat solar panel. In an embodiment, the solar cube is configured to generate about 4.75 times more electricity in one square unit of space than the standard flat solar panel.

In an embodiment, a solar cube device comprises five solar panels; a frame configured to hold five solar panels into a box shape with one open end; a lens configured to refract solar radiation onto the interior surface of five solar panels, wherein the lens is located in the open end of the box shape; electrically conductive wire; and an electrical storage battery, wherein the battery is electrically interconnected to the five solar panels through the electrically conductive wire. In an embodiment, the solar cube device is configured to convert solar radiation refracted from the lens into about 4 times more electrical energy per square unit of space compared to a flat solar panel.

In a further embodiment, five solar panels are electrically interconnected in series to the electrical storage battery.

In yet another embodiment, the five solar panels are electrically interconnected in parallel to the electrical storage battery.

In one embodiment, the lens is a double concave lens.

In still another embodiment, the position of the lens is adjustable.

In an embodiment, at least two solar cube devices are electrically interconnected in series.

In yet another embodiment, at least two solar cube devices are electrically interconnected in parallel.

In a further embodiment, the electrical storage battery is further electrically interconnected to an electrically powered device.

In one embodiment, the electrical storage battery is further electrically interconnected to an electrically powered device.

Various objects, features, aspects and advantages of the inventive subject matter will become more apparent from the following detailed description of exemplary embodiments, along with the accompanying figures in which like numerals represent like components.

### BRIEF DESCRIPTION OF THE DRAWINGS

FIG. 1 is an angled side view of an exemplary configuration of a solar cube.

FIG. 2 is an angled side view of an exemplary configuration of a solar cube without the lens to depict the inside of the cube.

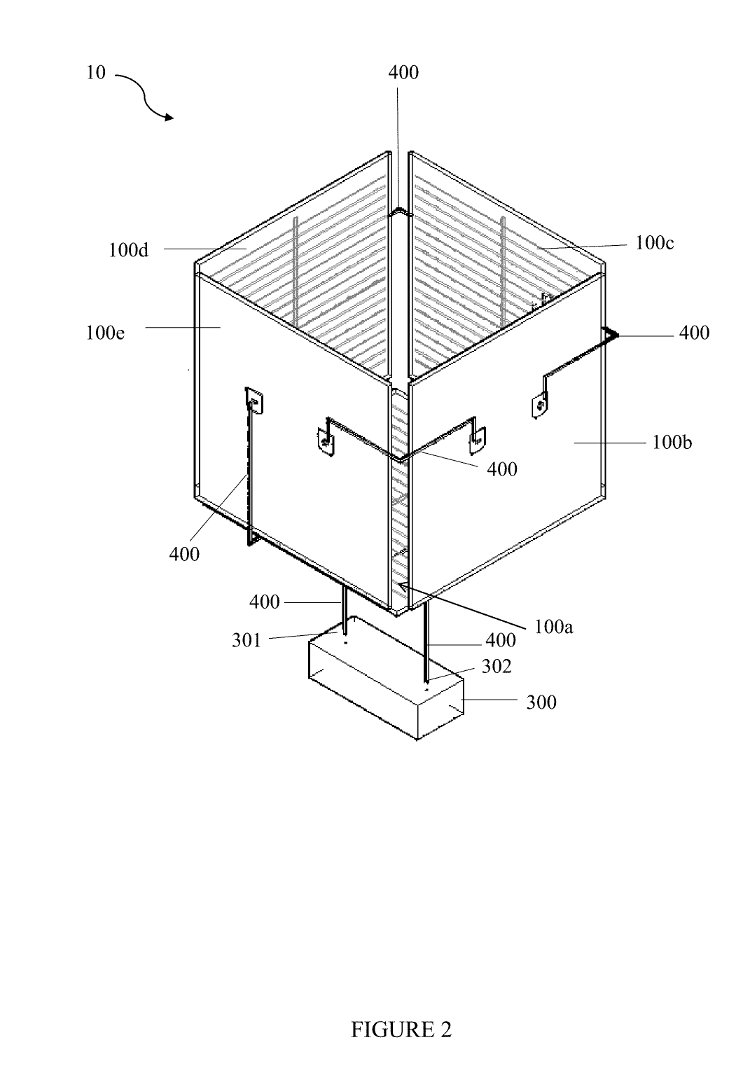

FIG. 3 is a transverse view of the solar cube with refraction of light rays from the sun illustrating the direction of the light reaching the walls of the solar cube.

FIG. 4 is a schematic of one solar panel with positive and negative connection points shown.

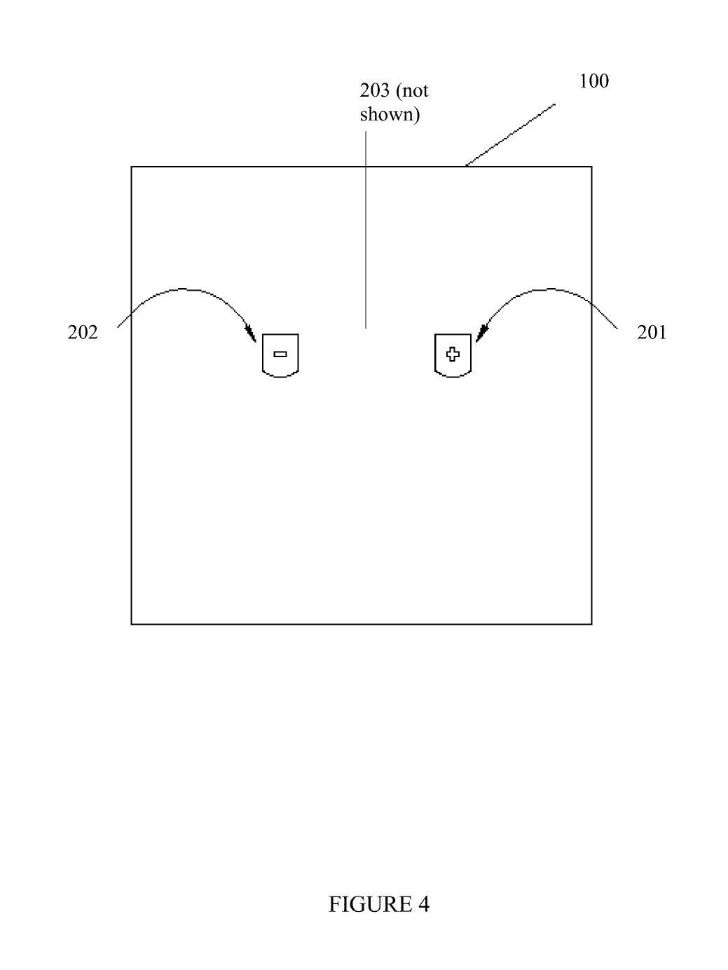

FIG. 5 is a schematic of the circuitry between one solar panel and the battery.

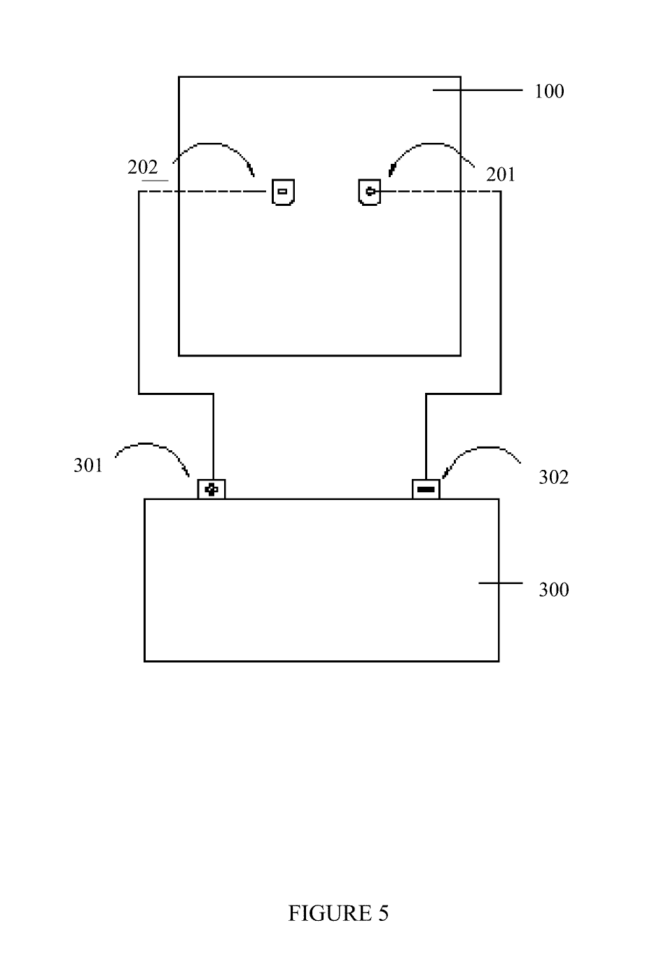

FIG. 6 is a schematic of the circuitry between five solar panels of the solar cube and the battery.

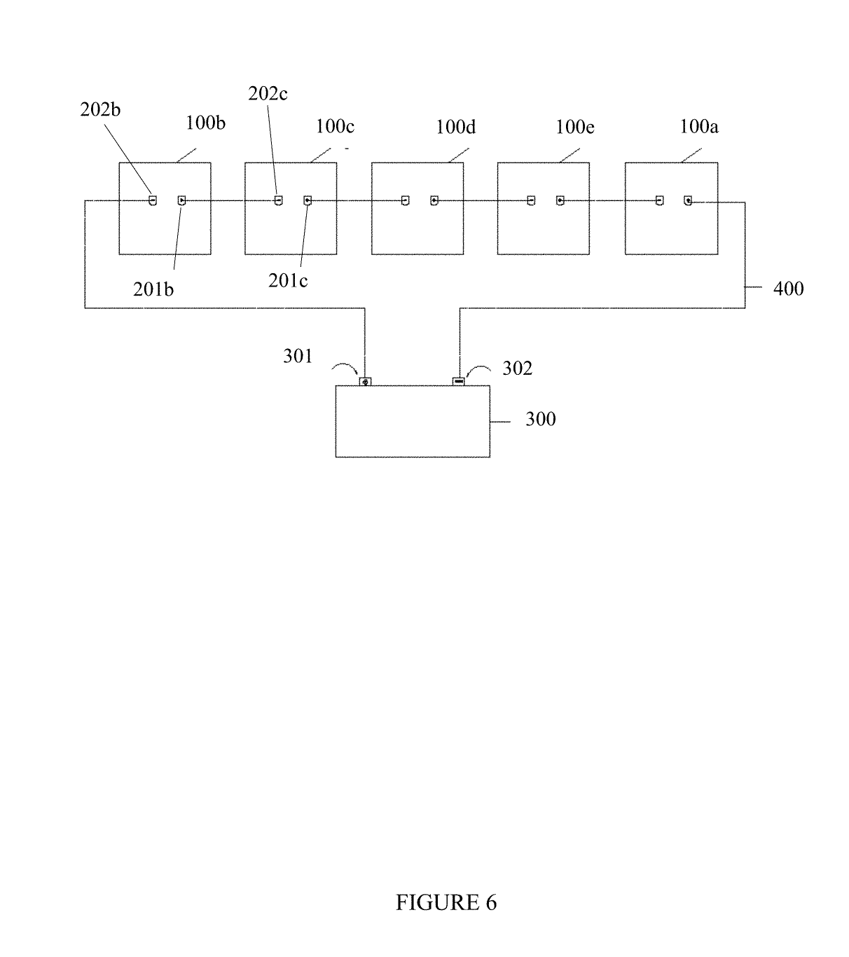

FIG. 7 is an exemplary embodiment of the metal frame that surrounds each solar panel.

FIG. 8 is an exemplary embodiment of a panel of the interior of the metal frame and solar panel.

FIG. 9 is an exemplary embodiment of two panels of the metal frame and their connection points.

FIG. 10 is an exemplary embodiment of the metal frame that surrounds the entire solar cube.

FIG. 11 is an exemplary embodiment of the gimbal ring and connecting brackets that are used to secure the lens in place.

FIG. 12 is an exemplary embodiment of the metal frame in a cube formation with gimbal ring and the connecting brackets attached.

FIG. 13 is an exemplary embodiment of the solar cube with metal frame with the gimbal ring shown.

FIG. 14 is a depiction of the metal frame in a cube formation with an additional metal frame added to show how adjacent solar cube metal frames can fit together.

FIG. 15 is an exemplary embodiment of solar cubes in a series configuration.

FIG. 16 is an exemplary embodiment of multiple adjacent solar cubes arranged in an array.

### DETAILED DESCRIPTION

A solar cube device is designed to generate more electricity in one square unit of space than the standard flat solar panel. In an embodiment, the solar cube is configured to generate about 4.75 times more electricity in one square unit of space than the standard flat solar panel.

As used herein, and unless the context dictates otherwise, the term “solar cube device” and “device” are used interchangeably. As used herein, and unless the context dictates otherwise, the term “solar radiation” and “sunlight” may be used interchangeably.

As used in the description herein and throughout the claims that follow, the meaning of “a,” “an,” and “the” includes plural reference unless the context clearly dictates otherwise. Also, as used in the description herein, the meaning of “in” includes “into” and “on” unless the context clearly dictates otherwise.

As used herein, the term “about” in conjunction with a numeral refers to a range of that numeral starting from 10% below the absolute of the numeral to 10% above the absolute of the numeral, inclusive.

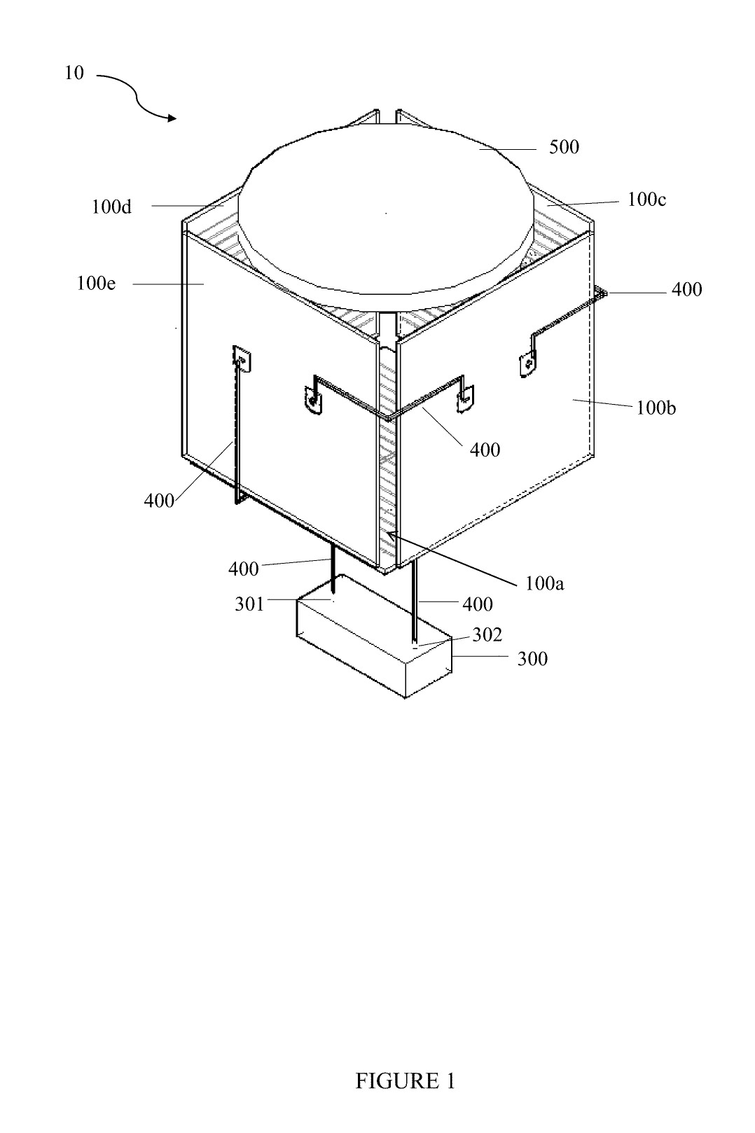

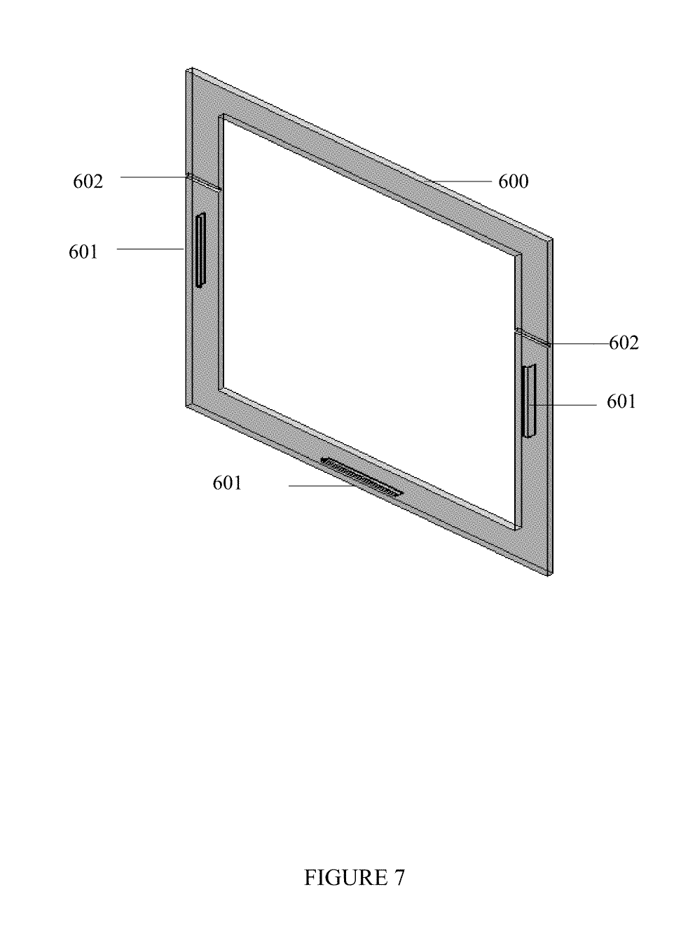

In an exemplary embodiment depicted in FIG. 1, a solar cube device 10 comprises five solar panels 100a to 100e configured to form a box shape having an open end and a closed end, with individual solar panel 100a forming the closed end of the box shape, and solar panels 100b, 100c, 100d and 100e are connected along their respective edges to form the upright solar panels of the box shape as shown. The upright solar panels 100b to 100e are also connected along their separate respective edges to solar panel 100a that forms the closed end of the solar cube device 10. In one embodiment, metal frame 600 is configured to hold five solar panels 100a to 100e in a cubic configuration. In an embodiment, metal frame 600 is configured to hold four solar panels 100b to 100e in a vertical position and one solar panel 100a in a relatively perpendicular position with respect to the four vertical solar panels 100b to 100e and further configured to uphold the entire structure of solar cube device 10 (FIG. 7), with solar panel 100a serving as the base of the solar cube device 10 and solar panels 100b to 100e serving as the enclosing sides of the solar cube device 10.

In an embodiment, concave lens 500 is mounted in the open end of the box shape formed by the intersection of the top edge of solar panels 100b to 100e, as shown. Sunlight is collected by the integrated solar panels 100a to 100e and this sunlight energy is converted into electrical energy via the solar panels 100a to 100e, and this electrical energy flows into and is stored in a battery 300 electrically interconnected with the solar panels 100a to 100e. A series of wires 400 electrically interconnects solar panels 100a to 100e, so that the electrical current generated within a solar panel due to conversion of sunlight energy that is collected through the lens 500 and convened within the solar panels 100a to 100e to electrical energy flows from the positive (excess) connection point on one solar panel to the negative (deficient) connection point on the adjacent solar panel and then out through the positive connection point on that same solar panel to the adjacent solar panel's negative connection point, and so forth until the electrical energy flow eventually reaches the negative connection point of the battery 300 and the electrical energy reaching the battery 300 is stored therein for later use. For example, as depicted in an exemplary embodiment in FIG. 1, in the solar cube device 10, electrical energy from the positive connection point (not shown) on solar panel 100b directionally flows to the negative connection point (not shown) on solar panel 100c, and in turn the electrical energy continues to flow through the electrical path along wires 400 toward the battery negative connection point 302, so that the electrical energy generated through the solar cube device 10 is stored in the battery 300 and is later available for use as desired or needed. In an embodiment, positive connection point 301 of battery 300 as shown is electrically interconnected to a device (not shown) to be powered by the electrical energy stored in the battery 300. In one embodiment, wires 400 electrically interconnect solar panels 100a to 100e in series or in parallel.

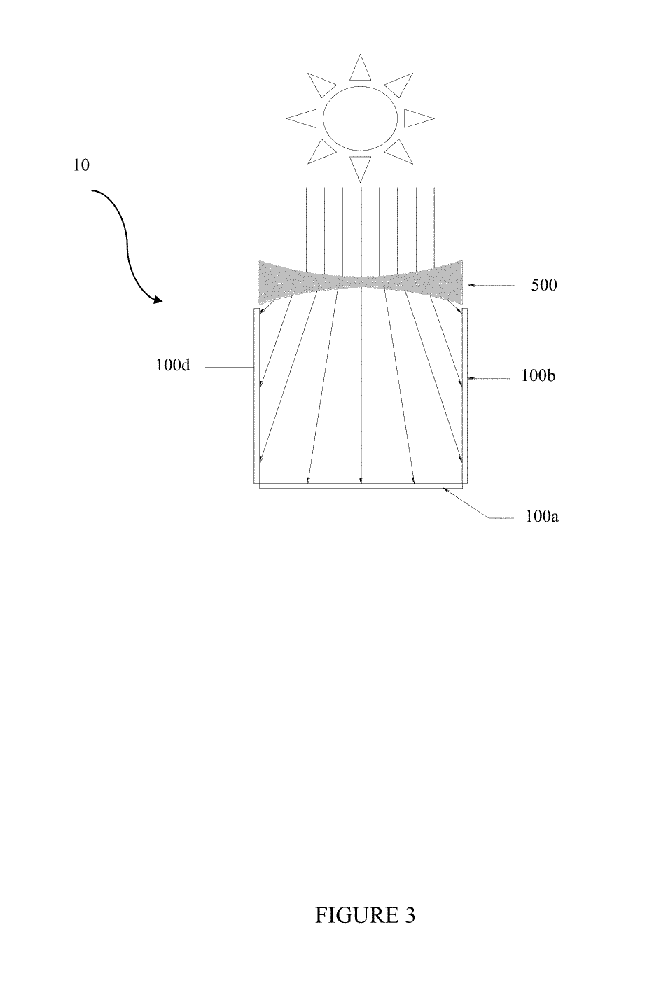

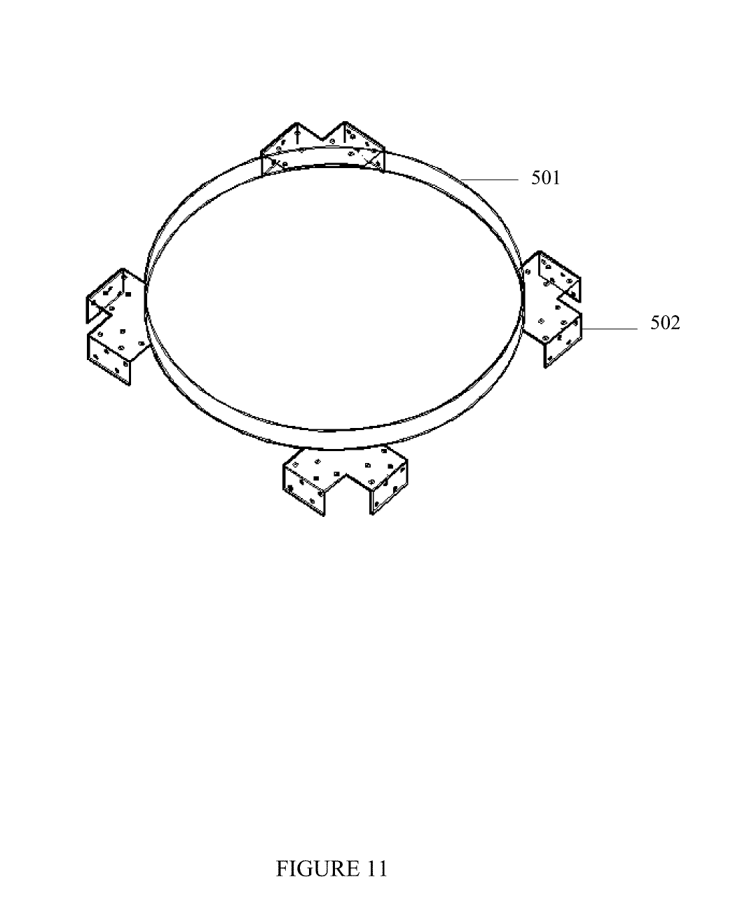

FIG. 1 also shows concave lens 500 occupying the open end of solar cube device 300. As depicted in an exemplary embodiment in FIG. 11, concave lens 300 is held in place by a gimbal ring 501 and connecting brackets 502 for mounting to corner intersection points (not shown) of solar panels 100b to 100e in solar cube device 10. As shown in FIG. 3, sunlight enters through concave lens 500 and the entering light is refracted onto the interior collection surfaces of solar panels 100a to 100e (only solar panels 100a, 100b and 100d are shown in the 2-dimensional drawing in FIG. 3). Concave lens 500 causes refracted sunlight to impact solar panels 100a to 100e at multiple points on each solar panel 100a to 100e, thereby maximizing the refracted light energy for collection and conversion to electrical energy by each respective solar panel 100a to 100e.

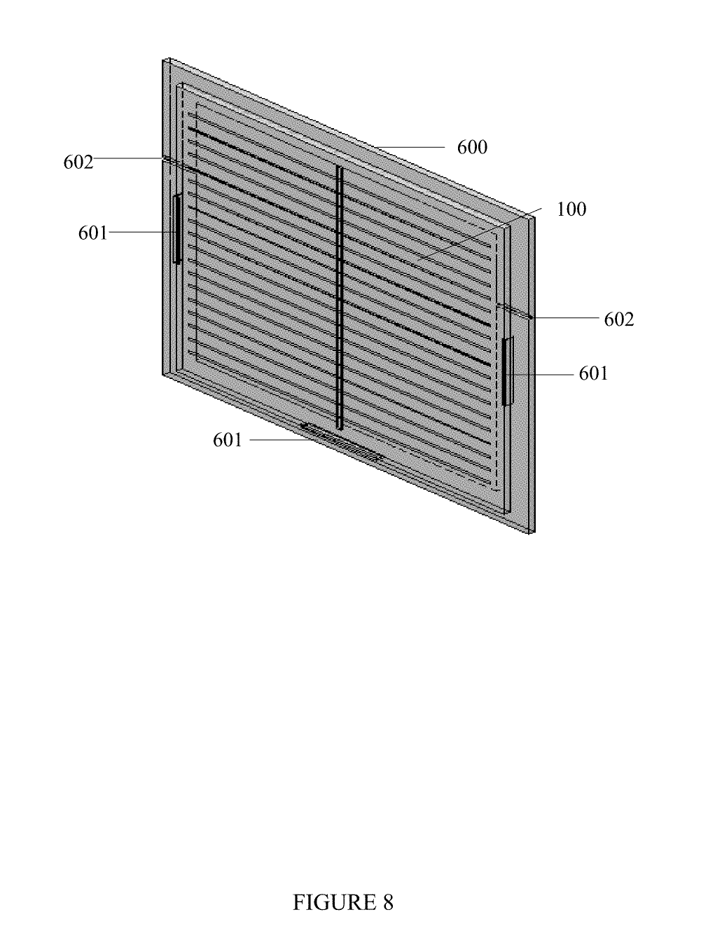

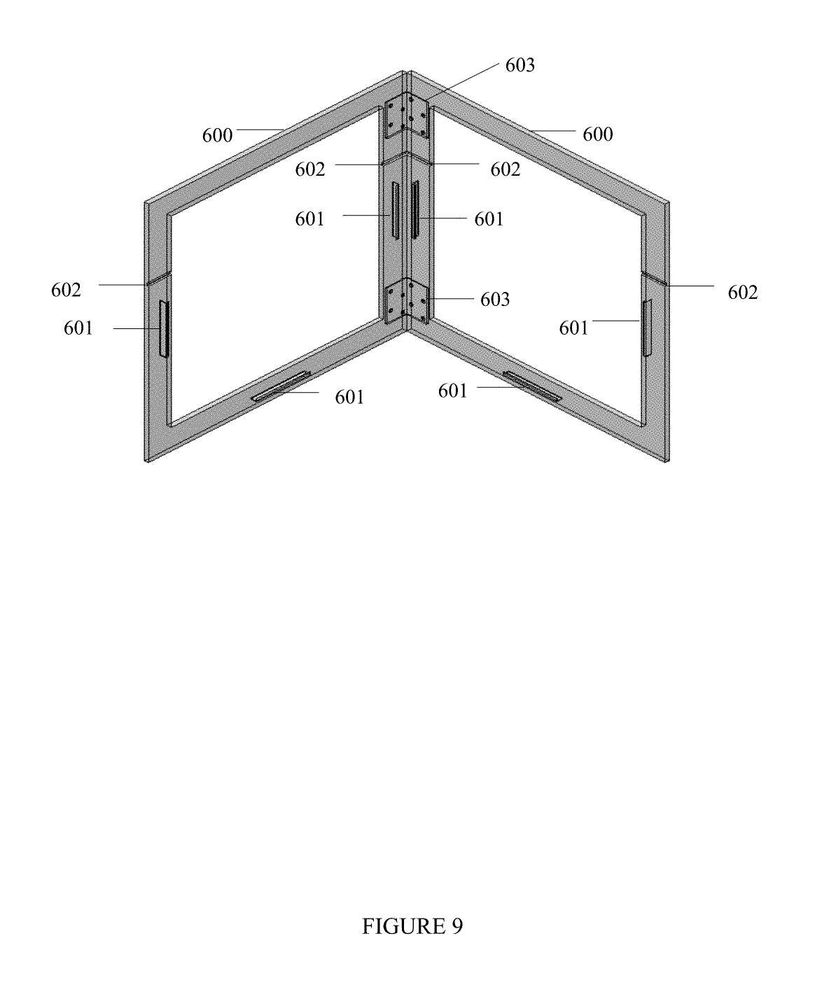

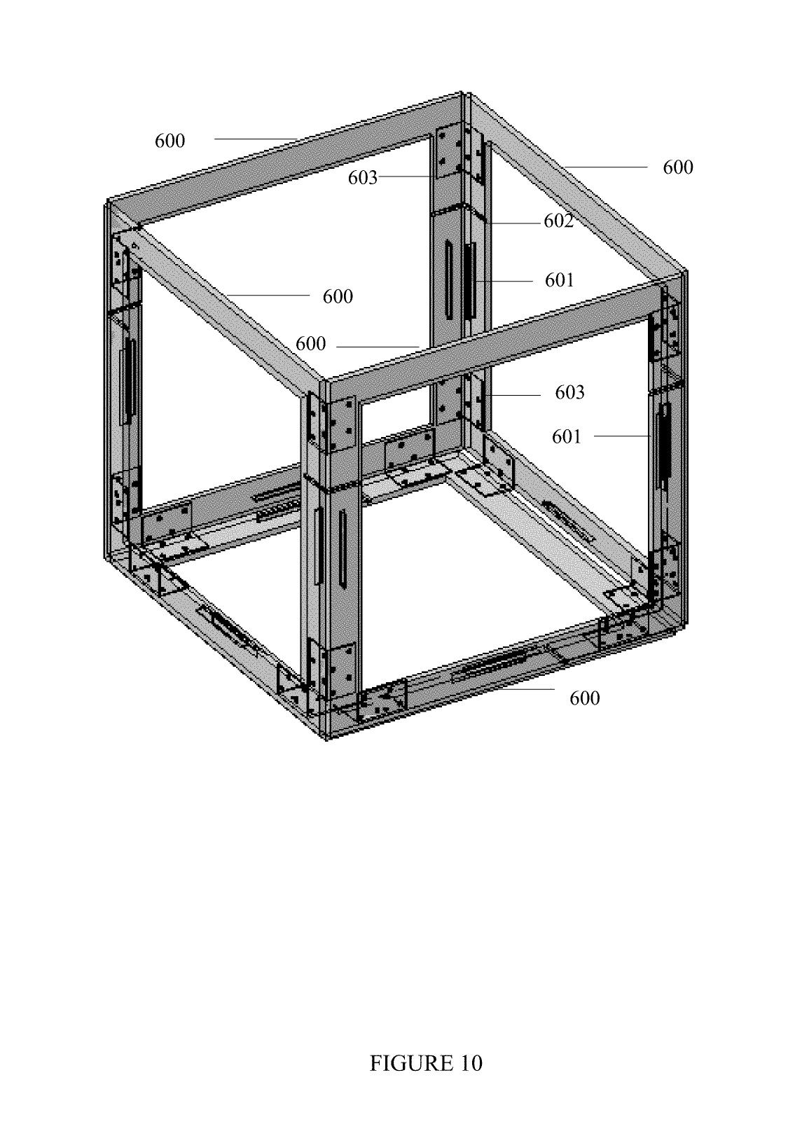

FIGS. 7 and 8 depict metal frame 600 configured to hold each solar panel 100 in place to form a cube. In one embodiment, each frame 600 contains frame clips 601 that are on either side of solar panel 100 and configured to secure solar panel 100 in place. In one embodiment, frame grooves 602 are configured to allow wire 400 to pass through unencumbered to the next solar panel 100. In another embodiment, an L bracket 603 is utilized to connect each metal frame 600 together at 90 degrees to form a cube configuration. An exemplary embodiment of a connection between two metal frames 600 and four frames 600 are shown in FIGS. 9 and 10, respectively. In one embodiment, each metal frame 600 is about 1.10% larger than one solar panel 100. In one embodiment, frame 600 comprises aluminum, aluminum-steel alloy, carbon fiber, polymer composite or any combination thereof. In one embodiment, metal frame 600 is configured to be open in the center to allow cooling of each solar panel 100 to increase efficiency and decrease weight of the cube.

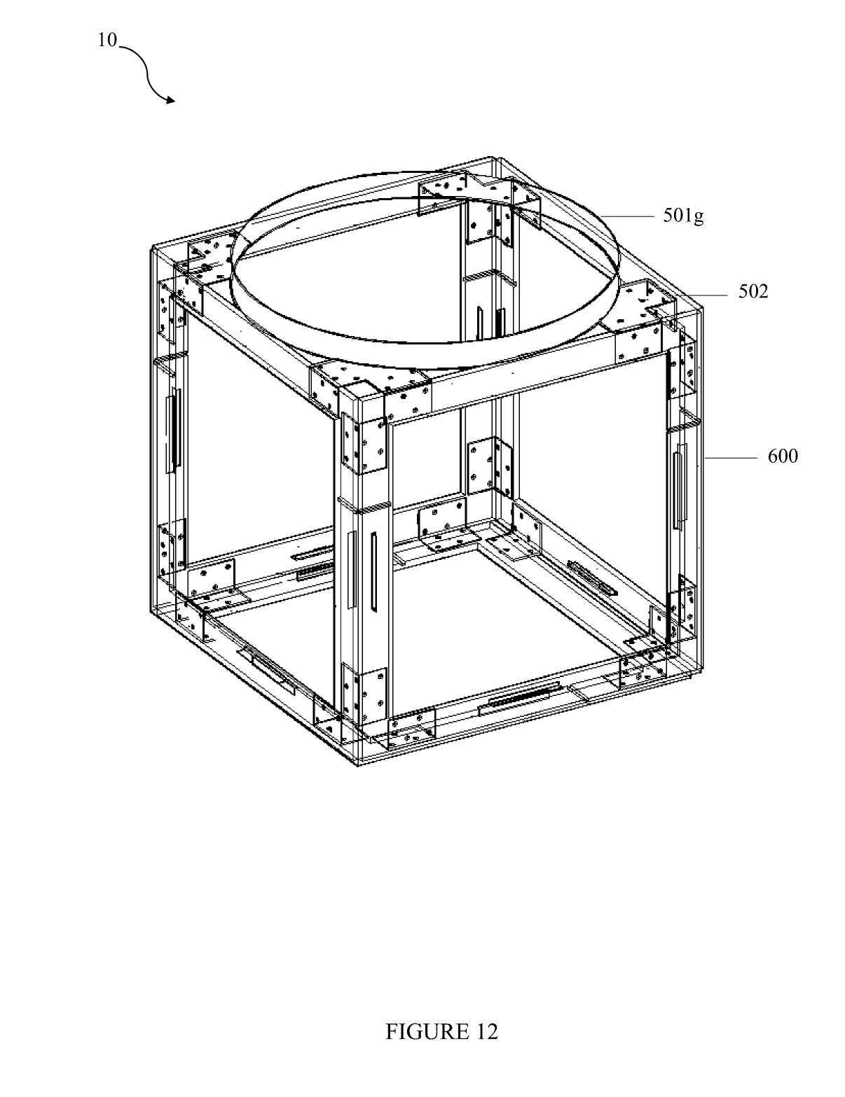

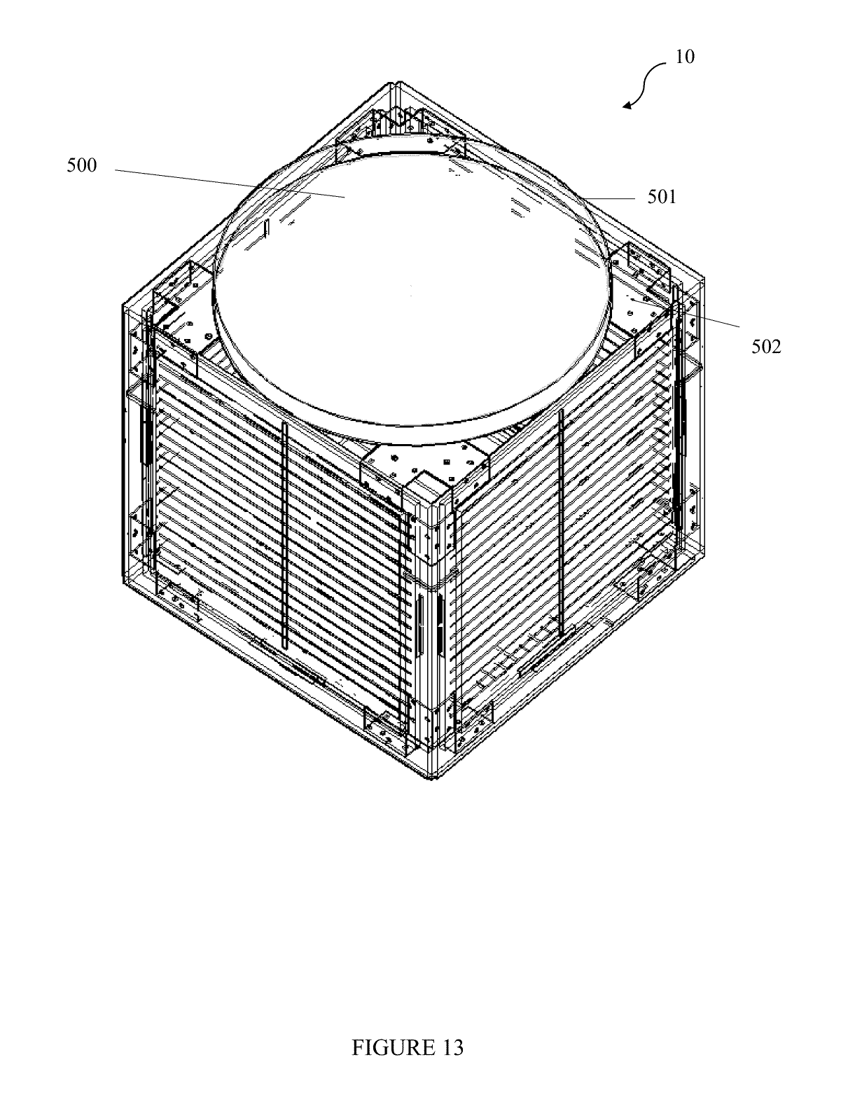

FIGS. 11 to 13 depict the attachment of gimbal ring 501 to metal frame 600 utilizing connecting brackets 502 to uphold the structure of solar cube device 10. In an exemplary embodiment, gimbal ring 501 is the same thickness as lens 500. In one embodiment, gimbal ring 501 is proportional to the size of concave lens 500. In another embodiment, concave lens 500 is proportional to the size of solar panel 100. One of ordinary skill in the art will envision the suitable size for lens 500, gimbal ring 501 and solar panel 100, based on the application of solar cube device 10. In another embodiment, device 10 comprises four connecting brackets 502 that connects panel 100 to four vertical sides of solar cube device 10. In another embodiment, L brackets 603 connect the corner of solar panel 100 located on the bottom of solar cube device 10 to four vertical sides of solar cube device 10.

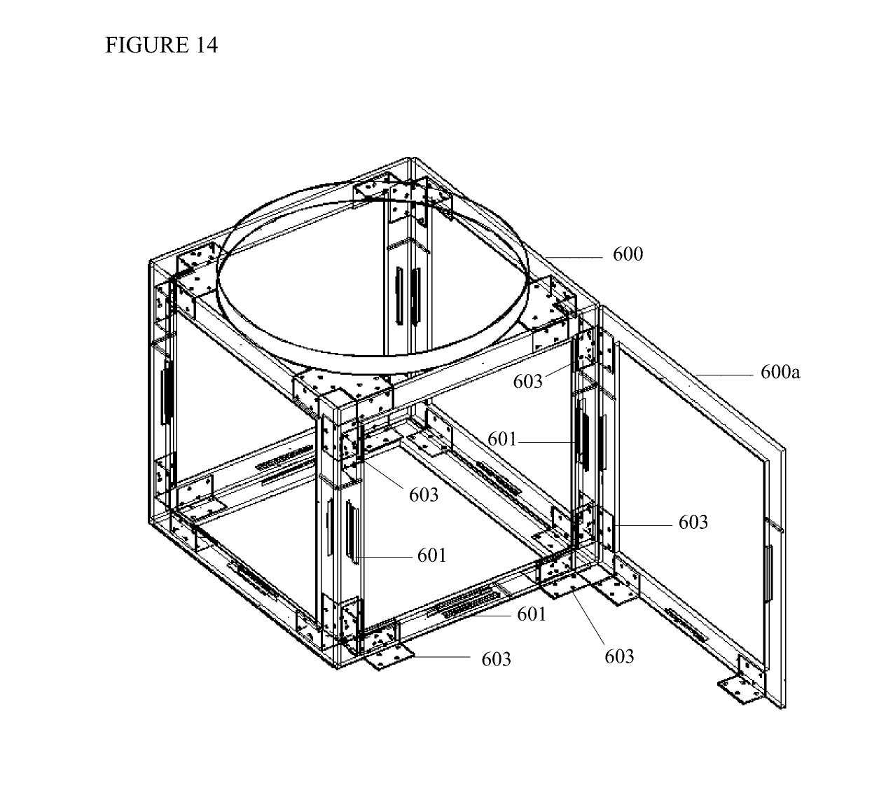

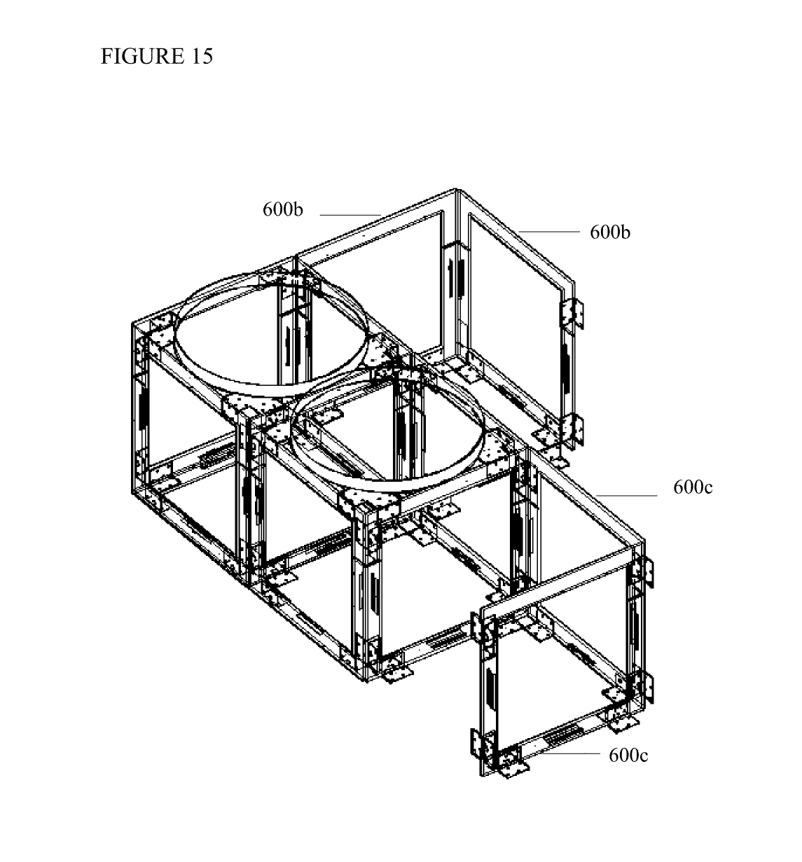

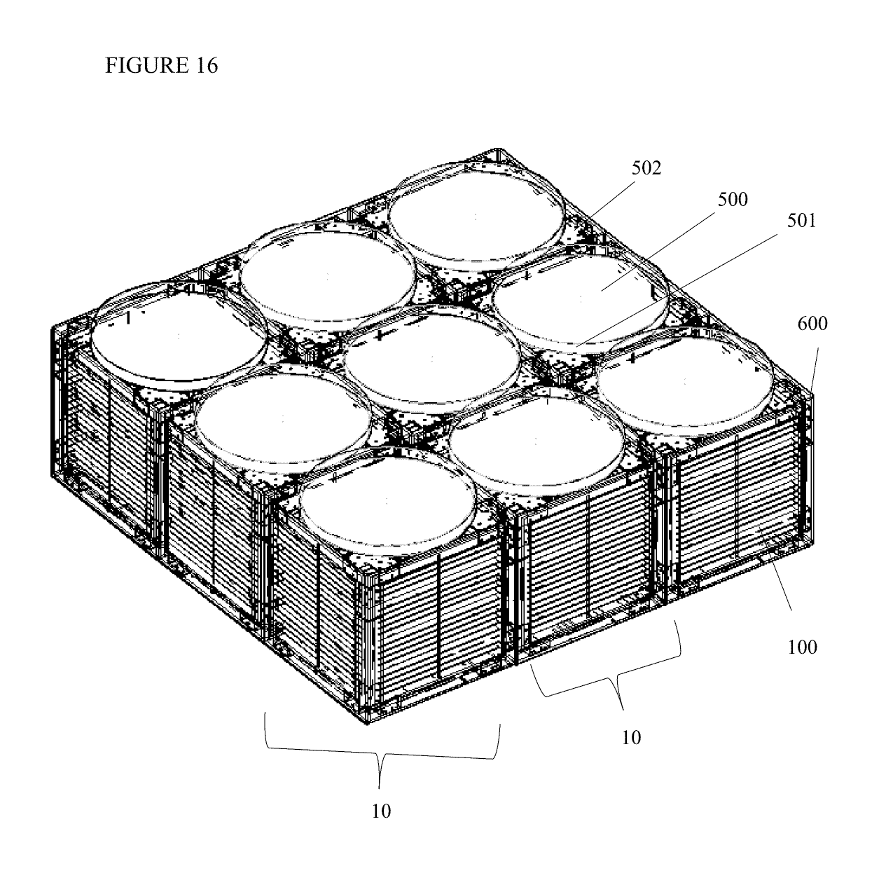

FIG. 14 illustrates the connection between two adjacent metal frames 600 and 600(a) to allow two solar cube device 10 to connect through the use of L brackets 603. As FIG. 15 illustrates, multiple metal frames, 600, 600a, and 600b can be connected together to achieve maximum efficiency of space FIG. 16 is an exemplary depiction of multiple adjacent solar cube device 10, wherein solar cube devices 10 as depicted are electrically interconnected through wires 400.

In an exemplary embodiment, each solar panel 100 is about 68 square centimeters, rated at a 2.00-volt output and 200 milliamps.

In another embodiment, lens 500 is about 57.1 centimeters in diameter and has a diopter rating of −1.24.

In another embodiment, solar cube device 10 generates 475% more electricity per square unit of space than a flat solar panel. In yet another embodiment, solar cube device 10 with the concave lens 500 generates 447.8% more electricity per square unit of space than a flat solar panel.

In an exemplary embodiment, an array of 9 solar cube devices 10, shown in FIG. 16, each of the five 68 cm solar panels 100 have an average output of 2.34 volts. The collective output of the array is 95.4 volts.

Thus, specific embodiments of a solar cube device have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

1. A solar cube device comprising:
five solar panels;
a frame configured to hold said five solar panels into a box shape with one open end;
a lens configured to refract solar radiation onto the interior surface of said five solar panels, wherein said lens is located in said open end of said box shape;
electrically conductive wire; and
an electrical storage battery, wherein said battery is electrically interconnected to said five solar panels through said electrically conductive wire; and
wherein said solar cube device is configured to convert solar radiation refracted from said lens into about 4 times more electrical energy per square unit of space compared to a flat solar panel.

2. A solar cube device according to claim 1 wherein said five solar panels are electrically interconnected in series to said electrical storage battery.

3. A solar cube device according to claim 1 wherein said five solar panels are electrically interconnected in parallel to said electrical storage battery.

4. A solar cube device according to claim 1 wherein said lens is a double concave lens.

5. A solar cube device according to claim 1 wherein the position of said lens is adjustable.

6. A solar cube device array comprising at least two solar cube devices of claim 1 electrically interconnected in series.

7. A solar cube device array comprising at least two solar cube devices of claim 1 electrically interconnected in parallel.

8. A solar cube device according to claim 1 wherein said electrical storage battery is further electrically interconnected to an electrically powered device.

9. A solar cube device array according to claim 6 wherein said electrical storage battery is further electrically interconnected to an electrically powered device.

10. A solar cube device array according to claim 7 wherein said electrical storage battery is further electrically interconnected to an electrically powered device.
